(19) United States
(12) Patent Application Publication
(10) Pub. No.: US 2021/0234114 A1
(43) Pub. Date: Jul. 29, 2021

(54) ELECTROLUMINESCENT DISPLAY PANEL AND DISPLAY APPARATUS

(71) Applicant: BOE TECHNOLOGY GROUP CO., LTD., Beijing (CN)

(72) Inventors: Yapeng Li, Beijing (CN); Xiaoliang Ding, Beijing (CN); Haisheng Wang, Beijing (CN); Pengpeng Wang, Beijing (CN); Yuanyuan Ma, Beijing (CN); Yangbing Li, Beijing (CN); Xueyou Cao, Beijing (CN)

(73) Assignee: BOE TECHNOLOGY GROUP CO., LTD., Beijing (CN)

(21) Appl. No.: 16/762,279

(22) PCT Filed: Dec. 23, 2019
(86) PCT No.: PCT/CN2019/127456

§ 371 Date: May 7, 2020

(30) Foreign Application Priority Data
Mar. 29, 2019 (CN) 201910249885.1

(51) Int. Cl. H01L 51/50; H01L 51/52; H01L 27/32

(52) U.S. Cl. CPC H01L 51/5012; H01L 27/3227; H01L 27/326; H01L 51/5284

(57) ABSTRACT

The embodiments of the present disclosure relates to an electroluminescent display panel. The electroluminescent display panel may include an array substrate; a package cover opposite the array substrate; a plurality of electroluminescent components on a side of the array substrate facing the package cover; a plurality of photosensitive units; and a mask layer between the plurality of electroluminescent components and the package cover. Each of the plurality of photosensitive units may be between two adjacent electroluminescent components, and the photosensitive units may be configured to sense light in a non-visible light spectrum.

### CROSS-REFERENCE TO RELATED APPLICATIONS

This application claims benefit of the filing date of Chinese Patent Application No. 201910249885.1 filed on Mar. 29, 2019, the disclosure of which is hereby incorporated in its entirety by reference.

### TECHNICAL FIELD

The disclosure relates to the field of display technology, in particular, to an electroluminescent display panel and a display apparatus.

### BACKGROUND

With continuous development of display technology, people have higher and higher requirements on the quality of display panels, and the integration of display panels has become focus of attention.

In the related art, a display apparatus includes a display panel, a front camera, and/or a rear camera, wherein the cameras enable the display apparatus to have an imaging function, thereby improving diversification of the functions of the display apparatus. However, the cameras are provided as separate components on the display apparatus, especially the front camera which occupies a certain area of the display panel. Such a design is disadvantageous for the display panel to perform a full screen display.

### BRIEF SUMMARY

An embodiment of the present disclosure provides an electroluminescent display panel. The electroluminescent display panel may include an array substrate; a package cover opposite the array substrate; a plurality of electroluminescent components on a side of the array substrate facing the package cover; a plurality of photosensitive units, each of the plurality of photosensitive units between two adjacent electroluminescent components, the photosensitive units being configured to sense light in a non-visible light spectrum; and a mask layer between the plurality of electroluminescent components and the package cover. The mask layer may include first regions and second regions, each of the first regions may be configured to transmit light in a visible light spectrum and light in the non-visible light spectrum, each of the second regions may be configured to transmit only the light in the visible light spectrum, and the mask layer may be configured to process the light in the non-visible light spectrum incident from a side of the package cover so that the light in the non-visible light spectrum forms an image on the plurality of photosensitive units.

Optionally, each of the photosensitive units comprises a photosensitive device and a first wavelength band filtering film on a side of the photosensitive device facing the mask layer, the first wavelength band filtering film is configured to transmit only the light in the non-visible light spectrum, an orthographic projection of the first wavelength band filtering film on the array substrate covers an orthographic projection of the photosensitive device on the array substrate, and the orthographic projection of the first wavelength band filtering film on the array substrate does not overlap with an orthographic projection of the electroluminescent components on the array substrate.

Optionally, the first wavelength band filtering firm comprises high-transmission color resistant which transmits near-infrared light and has a transmittance of near-infrared light of 90%.

Optionally, the photosensitive device is in a same layer as the photosensitive units.

Optionally, the electroluminescent display panel further comprises a light shielding structure around each of the photosensitive units to ensure each of the photosensitive units is only exposed to light on a side facing away from the array substrate.

Optionally, the light shielding structure comprises a black matrix.

Optionally, the non-visible light spectrum includes infrared light or ultraviolet light.

Optionally, the mask layer comprises a second wavelength band filtering film in each of the second regions, and the second wavelength band filtering film is configured to transmit only the light in the visible light spectrum.

Optionally, the second wavelength band filter film comprises glass materials or resin materials.

Optionally, the array substrate further comprises first driving circuits for driving the electroluminescent components, and second driving circuits for driving the photosensitive units, wherein the first driving circuits are disposed in the same layer as the second driving circuits; the electroluminescent components are above the first driving circuits respectively; and the photosensitive units are above the second driving circuits respectively.

Optionally, the electroluminescent display panel comprises a plurality of pixel units, each of the pixel units comprises more than one of the electroluminescent components, and each of the photosensitive units is between two adjacent pixel units.

Optionally, the electroluminescent display panel further comprises a polarizer and a ¼ wave plate between the electroluminescent components and the mask layer or between the mask layer and the package cover.

Optionally, the electroluminescent components are configured to emit light of different primary colors respectively.

Optionally, the electroluminescent components are configured to emit white light, and a color film layer is between each of the electroluminescent components and the package cover and configured to convert the white light into a light of a primary color.

Optionally, an area of the mask layer corresponding to each of the electroluminescent components is multiplexed into the color film layer.

Optionally, the electroluminescent components are configured to emit blue light, a color conversion layer is between each of the electroluminescent components and the package cover and configured to convert the blue light into a light of a primary color.

Optionally, the mask layer is on a side of the color conversion layer facing the package cover.

Optionally, the first regions and the second regions are alternately arranged, and a width or diameter of each of the first regions is in a range between about 10 μm and about 100 μm.

One embodiment of the present disclosure is a display apparatus, comprising the electroluminescent display panel according to one embodiment of the present disclosure.

Optionally, the display apparatus further comprises an image processing module, wherein the image processing module is configured to acquire signals provided by the photosensitive units and process the signals to form an image of a scene.

### BRIEF DESCRIPTION OF THE DRAWINGS

The drawings are used to provide a further understanding of the technical solutions of the present disclosure, and constitute a part of the specification, which together with the embodiments of the present disclosure are used to explain the technical solutions of the present disclosure, and do not constitute a limitation of the technical solutions of the present disclosure. Obviously, the drawings in the following description are only some embodiments of the present disclosure, and those skilled in the art can obtain other drawings according to these drawings without any creative work.

FIG. 1 is a schematic structural diagram of an electroluminescent display panel according to one embodiment of the present disclosure;

FIG. 2 is a schematic structural diagram of a mask layer according to one embodiment of the present disclosure;

FIG. 3 is a schematic diagram of an arrangement structure of photosensitive units and electroluminescence components according to one embodiment of the present disclosure;

FIG. 4 is a schematic structural diagram of an electroluminescent display panel according to one embodiment of the present disclosure;

FIG. 5 is a schematic structural diagram of an electroluminescent display panel according to one embodiment of the present disclosure.

### DETAILED DESCRIPTION

The specific embodiments of the present disclosure are described in details below with reference to the accompanying drawings. It is understandable that the preferred embodiments described herein are intended to illustrate and explain the disclosure and are not intended to limit disclosure. The same reference numerals in the drawings denote the same or similar structures, and thus their detailed description will be omitted.

Although relative terms such as “above” and “below” are used in the specification to describe the relative relationship of one component to another component, these terms are used in this specification for convenience only, for example, in the accompanying drawings such that the direction of the example described. It is understandable that if the device of the icon is flipped upside down, the component described “above” will become the component “below”. When a structure is “on” another structure, it may mean that a structure is integrally formed on another structure, or that a structure is “directly” disposed on another structure, or that a structure is “indirectly” disposed through another structure on other structures.

The terms “a,” “an,” “the,” and “said” are used to mean presence of one or more elements/components, etc.; the terms “including” and “having” are used to mean the inclusiveness, meaning that there may be additional elements/components/etc. in addition to the listed elements/components/etc. In addition, the terms “first” and “second” are for illustration purposes only and are not to be construed as indicating or implying relative importance or implied reference to the quantity of indicated technical features. Thus, features defined by the terms “first” and “second” may explicitly or implicitly include one or more of the features. A number modified by “about” herein means that the number can vary by 10% thereof.

In the related art, the imaging unit occupies an area of the display panel, and is disadvantageous for the display panel to perform a full screen display. Some embodiments of the present disclosure provide an electroluminescent display panel and a display apparatus. The present disclosure will be further described in detail with reference to the accompanying drawings. All other embodiments obtained by those of ordinary skill in the art based on the embodiments of the present disclosure without creative efforts are within the protection scope of the present disclosure.

The shapes and sizes of the various components in the drawings do not reflect true proportions, and are merely intended to illustrate the present disclosure.

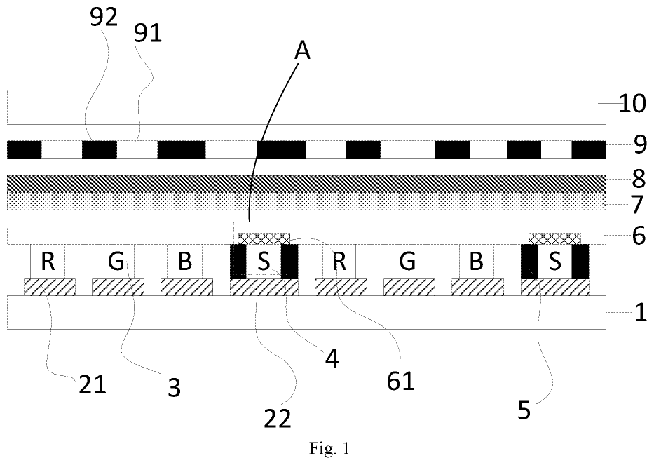

One embodiment of the present disclosure provides an electroluminescent display panel, as shown in FIG. 1, comprising: an array substrate 1 and a package cover 10, and a plurality of electroluminescent components 3 disposed on the side of the array substrate 1 facing the package cover 10. The electroluminescent display panel also may further comprise:

a plurality of photosensitive units A, and each photosensitive unit is located between two adjacent electroluminescence components 3, and configured to sense non-visible light in a non-visible light spectrum;

a mask layer 9 disposed between the electroluminescent components 3 and the package cover 10, wherein the mask layer 9 comprises first regions 91 and second regions 92 arranged in a predetermined pattern. The first region 91 is configured to transmit light in visible and non-visible light spectrums, and the second region 92 is used to transmit only light in a visible light spectrum. The mask layer 9 is used to process light in the non-visible light spectrum incident from the side of the package cover 10, such that the processed light in the non-visible light spectrum forms an on the photosensitive unit A.

In the electroluminescent display panel provided by one embodiment of the present disclosure, each photosensitive unit is correspondingly arranged with 50 to 100 alternating first and second regions. In this way, each photosensitive unit can receive non-visible light transmitted through the 50 to 100 first regions, and an image is formed on the photosensitive unit. Depending on the design of the mask layer, the width or diameter of the first region may be between about 10 μm and about 100 μm. In some embodiments, the width or diameter of the first region may be about 10 μm, 30 μm, 50 μm or 100 μm, and the specific size is selected according to actual needs, which will not be specified herein.

In the electroluminescent display panel provided by one embodiment of the present disclosure, the electroluminescent display panel senses light in the non-visible light spectrum by providing photosensitive units between two adjacent electroluminescent components. Furthermore, a pattern of the mask layer disposed between the photosensitive units and the package cover is designed so that the non-visible light can form an image on the photosensitive units, thereby achieving integrating the imaging function into the electroluminescent display panel, avoiding disposing of a separate imaging unit occupying any area of the electroluminescent display panel, and facilitating the full-screen display of the electroluminescent display panel.

It should be noted that, in the electroluminescent display panel provided by one embodiment of the present disclosure, the non-visible light spectrum mainly includes infrared light and ultraviolet light. One of the wavelength bands may be selected for application, according to actual conditions, and will not be specified herein.

Optionally, in an electroluminescent display panel provided by one embodiment of the present disclosure, as shown in FIG. 1, the photosensitive unit A may include: a photosensitive device 4 and a first wavelength band filtering film 61 on a side of the photosensitive device 4 facing the mask layer 9, wherein the first wavelength band filtering film 61 is used to transmit only light in the non-visible light spectrum; and

an orthographic projection of the first wavelength band filtering film 61 on the array substrate 1 covers an orthographic projection of the photosensitive device 4 on the array substrate 1; and

an orthographic projection of the first wavelength band filtering film 61 on the array substrate 1 does not overlap with and an orthographic projection of the electroluminescent component on the array substrate 1.

In one embodiment, the photosensitive device is in a same layer as the electroluminescence components. The term “in a same layer” means that a top surface of the photosensitive device and a top surface of each of the electroluminescence components are on a substantially same level.

The first wavelength band filtering film may include high-transmission color resistant which transmits near infrared light and absorbs visible light. In one embodiment, the first wavelength band filtering film includes infrared penetrant ABS-A90, which is a black high-brightness material with a specific gravity of 1.08, a near-infrared band transmittance of up to 90%, a refractive index of 1.56, a high temperature resistance up to 90 degrees without softening, a very good fluidity, and high mechanical strength. The ABS-A90 is suitable for molding 3D Glasses cover, set-top box shell, set-top box receiving window, smart home central remote control shell, etc.

In one embodiment, the first wavelength band filtering film includes infrared penetrant PC-C92, which is extremely bright in appearance, strongly absorbs visible light, and highly transmits near-infrared light, with a maximum transmission value of 93%, high temperature resistance without deformation above 120 degrees, aging resistance, very high mechanical strength, and high resistant to falling without broken. PC-C92 is suitable for molding infrared monitoring night vision cameras, infrared camera lenses, robot infrared receiving windows, infrared automatic sensing windows, smart home central remote control, etc.

In one embodiment, the first wavelength band filtering film includes infrared penetrant PMMA-M95, which has a black appearance, is extremely smooth, has a visible light absorption rate of 99.9%, a near-infrared light transmission rate of up to 95%, and a high surface hardness of up to 2H. The actual plastic product surface usually requires coating and hardening. The PMMA-M95 is suitable for extruding sheets, plates, and injection molding. It can be used for VR glasses, infrared night vision lenses, infrared camera lenses, infrared automatic induction machine tools, etc.

In an electroluminescent display panel provided by one embodiment of the present disclosure, the photosensitive unit may further include a first wavelength band filtering film disposed on the photosensitive device, wherein the first wavelength band filtering film can transmit only non-visible light. Therefore, the photosensitive device can only receive non-visible light, that is, the photosensitive unit is only used to sense light in the non-visible light spectrum. Of course, the photosensitive unit can also be configured to sense only non-visible light by other means, such as by using a photosensitive device that only senses non-visible light. The actual setting is determined according to actual situation, and is not specifically limited herein.

Optionally, in an electroluminescent display panel provided by one embodiment of the present disclosure, as shown in FIG. 1, a light-shielding structure 5 is further disposed around the photosensitive unit A.

In one embodiment, in order to prevent the visible light emitted by the electroluminescent component from affecting the photosensitive unit, a light-shielding structure 5 is disposed around the photosensitive unit to block the visible light to ensure the photosensitive unit is only exposed to light on a side facing away from the array substrate, and the other sides thereof are not exposed to light.

In some embodiments, the light shielding structure comprises a black matrix.

Certainly, the light-shielding structure may be any other components capable of achieving light-shielding, and is not limited to the black matrix. In some embodiments, the light-shielding structure may be set as a film layer coated on the side of the photosensitive device except the side facing away from the array substrate. The actual setting is determined according to actual situation, and is not specifically limited herein.

Optionally, in an electroluminescent display panel provided by one embodiment of the present disclosure, the mask layer may further include: a second wavelength band filtering film in the second region; and

the second wavelength band filtering film is used to transmit only light in the visible light spectrum.

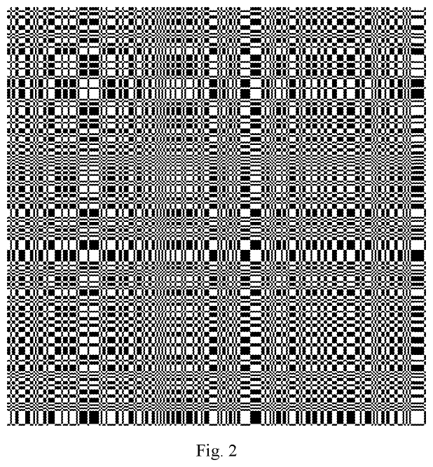

In one embodiment of the present disclosure, a patterned structure of the mask layer mode of photoresist is shown in FIG. 2. The pattern of the mask layer needs to ensure that the second regions (black regions) transmit only visible light. The first regions (white regions) can pass both visible light and non-visible light. The second region is configured to transmit only visible light by providing a second wavelength band filtering film in the second region, wherein the second wavelength band filtering film transmits only visible light, so that non-visible light cannot pass through, thereby achieving the non-visible light passing through the mask layer can form an image on the photosensitive units.

In one embodiment, the second wavelength band filtering film includes materials which transmits visible light and sbsorb near-infrared light. The near-infrared absorbing materials are mainly divided into glass materials and resin materials. Glass materials are prepared by adding ions into glass. Resin materials are mainly prepared by incorporating organic dyes with near-infrared absorption into the resin matrix. For example, ethoxyphenyl, butoxyphenyl, and hexadecyloxyphenyl are substituted for three thiodiene nickel complexes, and the three complexes are incorporated into PMMA resin by injection molding.

Optionally, an electroluminescent display panel provided by one embodiment of the present disclosure, as shown in FIG. 1, may further include: first driving circuits 21 for driving the electroluminescent components 3 on the array substrate 1, and second driving circuits 22 for driving the photosensitive units A; wherein

the first driving circuits 21 are disposed in the same layer as the second driving circuits 22; and

the electroluminescent component 3 is located above the first driving circuit 21, and the photosensitive unit A is above the second driving circuit 22.

In the electroluminescent display panel provided by one embodiment of the present disclosure, the first driving circuits and the second driving circuits are disposed in the same layer, so can be fabricated by the same process when fabricating each film layer of the two circuits. Such a method simplifies the preparation process, and also reduces the thickness of the display panel. Since the electroluminescent component is located above the first driving circuit with no other components interposed inbetween, the photosensitive unit is located above the second driving circuit, and no other components are disposed in between, so that the electroluminescent component and the photosensitive unit are located on the same layer. Therefore, the photosensitive unit does not occupy a whole layer. In this way, the imaging function can be integrated into the electroluminescent display panel without making a large change to the structure of the electroluminescent display panel.

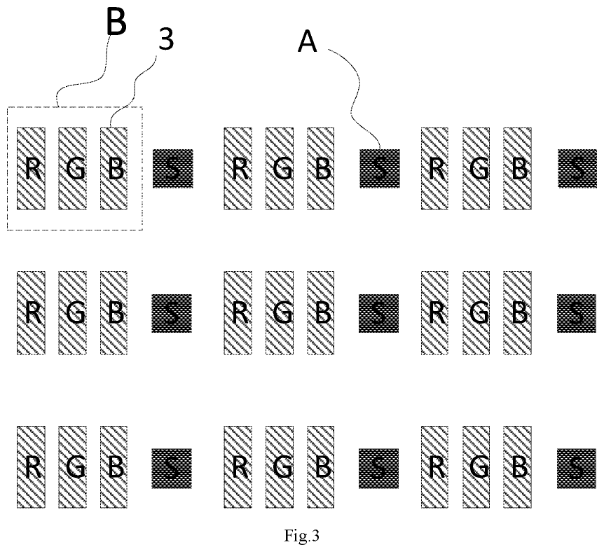

Optionally, an electroluminescent display panel provided by one embodiment of the present disclosure, as shown in FIG. 3, may further comprise a plurality of pixel units B, wherein each pixel unit B comprises a plurality of electroluminescent components 3; and

the photosensitive unit A is located between two adjacent pixel units B.

Optionally, the photosensitive unit may be located between two adjacent electroluminescent components, or between two adjacent pixel units. Optionally, a photosensitive unit is disposed between every two adjacent electroluminescent components, or a photosensitive unit may be disposed between two adjacent electroluminescent components according to a preset rule. Similarly, a photosensitive unit can be disposed between every two adjacent pixel units, or a photosensitive unit may be disposed between two adjacent pixel units according to a preset rule. The specific setting is determined according to the actual design of the electroluminescent display panel, and is not specifically limited herein.

Optionally, in an electroluminescent display panel provided by one embodiment of the present disclosure, as shown in FIG. 1, between the electroluminescent component 3 and the mask layer 9, it may further include: a polarizer 8 and a quarter-wave plate 7;

Or, between the mask layer 9 and the package cover 10, it may further include: a polarizer 8 and a quarter-wave (¼) plate 7.

Specifically, in an electroluminescent display panel provided by one embodiment of the present disclosure, when the electroluminescent component is used to display light of a corresponding color of each pixel, the polarizer and the ¼ wave plate may be located between the electroluminescent component and the mask, or may be located between the mask layer and the package cover. The specific setting is determined according to actual situation, and is not specifically limited herein.

Optionally, in the electroluminescent display panel provided by one embodiment of the present disclosure, the electroluminescent component is capable of emitting light of different primary colors.

In an electroluminescent display panel provided by one embodiment of the present disclosure, as shown in FIG. 1, the electroluminescent components 3 may include a red light emitting component R, a green light emitting component G, and a blue light emitting component B. Of course, according to the pixel design of the panel, it may also include a white light emitting component or other color light emitting component, which is not specifically limited herein.

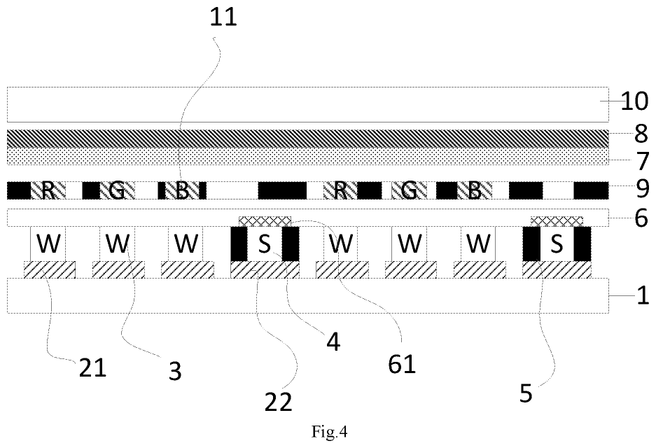

Optionally, in the electroluminescent display panel provided by one embodiment of the present invention, as shown in FIG. 4, when the electroluminescent device 3 is used to emit white light, the display panel further includes: a color film layer 11 between the electroluminescent device 3 and the package cover 10.

Optionally, in the electroluminescent display panel provided by one embodiment of the present disclosure, when all the electroluminescent devices are used to emit white light, a color film layer needs to be disposed between each of the electroluminescent devices and the package cover, so that each pixel may emit light of a corresponding color.

Optionally, in the electroluminescent display panel provided by one embodiment of the present disclosure, as shown in FIG. 4, the areas of the mask layer 9 corresponding to the electroluminescent components 3 are multiplexed into or commonly used as the color film layers 11.

Specifically, in the electroluminescent display panel provided by one embodiment of the present disclosure, when the electroluminescent display panel has a color film layer, the mask layer can be multiplexed into the color film layer. In this way, each area of the mask layer has no influence on the transmission of visible light. Therefore, as long as the areas of the mask layer corresponding to the electroluminescent components are respectively set to a color film layer corresponding to the color of the pixel, the display of the electroluminescent components and the image collection of the photosensitive units will not be affected.

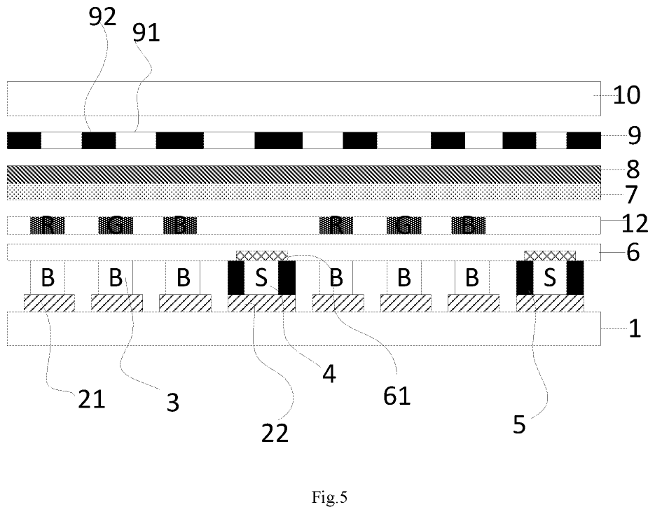

Optionally, in an electroluminescent display panel provided by one embodiment of the present disclosure, as shown in FIG. 5, when the electroluminescent component 3 is used for emitting blue light, the display panel may further include: a color conversion layer 12 disposed between the electroluminescent component 3 and the package cover 10.

Specifically, when all the electroluminescent components are set to emit blue light, the display panel needs to set a color conversion layer so that the corresponding pixel is used to emit a corresponding color. The material used in the color conversion layer is the same as the prior art, and is not specifically limited herein.

Optionally, in the electroluminescent display panel provided by one embodiment of the present disclosure, as shown in FIG. 5, the mask layer 9 can be disposed between the color conversion layer 12 and the package cover 10.

In some embodiments, in order to ensure the light conversion efficiency of the color conversion layer, the color conversion layer should be disposed to the electroluminescent components as close as possible. Therefore, the mask layer needs to be set on a side of the color conversion layer opposite from the array substrate.

Optionally, in the electroluminescent display panel provided by one embodiment of the present disclosure, as shown in FIG. 5, between the color conversion layer 12 and the package cover 10, a polarizer 8 and a quarter-wave (¼) plate 7 are included.

Specifically, in order to ensure the light conversion efficiency of the color conversion layer, the color conversion layer should be disposed to the electroluminescent component as close as possible. Therefore, the polarizer 8 and the ¼ wave plate 7 can be disposed on a side of the color conversion layer opposite from the array substrate, and the positions of the polarizer and the ¼ wave plate and the mask layer are interchangeable. The specific setting is determined according to the actual situation, and is not specifically limited herein.

Based on the same inventive concept, one embodiment of the present disclosure further provides a display apparatus, including the electroluminescent display panel provided by any of the above embodiments and an image processing module, wherein

the image processing module is configured to acquire signals provided by the photosensitive units and process the signals to form an image.

Specifically, in the display apparatus provided by one embodiment of the present disclosure, the mask layer in the electroluminescent display panel modulates the non-visible light emitted or reflected by the external scene, and enable the non-visible light to pass through the first regions distributed according to different rules, so that the photosensitive units receive the projection of the non-visible light to form an overlapped, degraded two-dimensional blurred image. That is, an image of the external scene is encoded in the electroluminescent display panel to form an intermediate image. Since the encoded optical system forms an overlapping multi-scene image on the surface of the photosensitive units, the image processing module is required to process the data provided by the electroluminescent display panel to obtain an image corresponding to the external scene

In one embodiment, the image processing module may be a hardware having a data processing function, such as a processor. The corresponding functional relationship is stored in the processor, as follows:

Y=M*O+e;

Wherein Y is an image signal obtained on the photosensitive unit, O is captured scene information, M is a system matrix, and e is a system error, wherein M and e are inherent parameters of the display apparatus. Based on the image signal obtained on the photosensitive unit, the captured scene information can be obtained, that is, the decoding of the intermediate image formed by the electroluminescent display panel is completed, the image corresponding to the scene is obtained, and the imaging is completed.

The display apparatus is applicable to various types of displays such as an organic electroluminescent display, an inorganic electroluminescence display, and an active Matrix/Organic Light Emitting Diode (AMOLED). The display apparatus may be any product or component having a display function, such as a mobile phone, a tablet computer, a television, a display, a notebook computer, a digital photo frame, a navigator, etc., which is not limited herein.

Embodiments of the present disclosure provide an electroluminescent display panel and a display apparatus. The electroluminescent display panel includes: an array substrate and a package cover, a plurality of electroluminescent components disposed on a side of the array substrate facing the package cover, and also a photosensitive unit disposed between two adjacent electroluminescence components, wherein the photosensitive unit is used for sensing light in a non-visible light spectrum. Between the electroluminescent components and the package cover, a mask layer may comprise first regions and second regions arranged according to a preset pattern, wherein the first region is used for transmitting light in a visible light spectrum and a non-visible light spectrum, the second region being used for transmitting only the visible light spectrum, and the mask layer is used to process the light in the non-visible light spectrum incident from the side of the package cover. In this way, the processed non-visible light spectrum forms an image on the photosensitive unit. The image collection can be realized by the arrangement of the photosensitive units and the mask layer, and the collected image can be processed by an independently arranged image processing module to obtain the image of the scene. Since the mask layer does not block the visible light, the photosensitive unit only collects non-visible light, thereby integrating the imaging function into the display panel without affecting the display of the display panel.

It is apparent that those skilled in the art can make various modifications and variations to the present disclosure without departing from the spirit and scope of the present disclosure. Thus, it is intended that the present disclosure covers the modifications and variations to the present disclosure.

1. An electroluminescent display panel, comprising:
an array substrate;
a package cover opposite the array substrate;
a plurality of electroluminescent components on a side of the array substrate facing the package cover;
a plurality of photosensitive units, each of the plurality of photosensitive units between two adjacent electroluminescent components, the photosensitive units being configured to sense light in a non-visible light spectrum; and
a mask layer between the plurality of electroluminescent components and the package cover,
wherein the mask layer comprises first regions and second regions, each of the first regions is configured to transmit light in a visible light spectrum and light in the non-visible light spectrum, each of the second regions is configured to transmit only the light in the visible light spectrum, and
the mask layer is configured to process the light in the non-visible light spectrum incident from a side of the package cover so that the light in the non-visible light spectrum forms an image on the plurality of photosensitive units.

2. The electroluminescent display panel according to claim 1, wherein each of the photosensitive units comprises a photosensitive device and a first wavelength band filtering film on a side of the photosensitive device facing the mask layer, the first wavelength band filtering film is configured to transmit only the light in the non-visible light spectrum, an orthographic projection of the first wavelength band filtering film on the array substrate covers an orthographic projection of the photosensitive device on the array substrate, and the orthographic projection of the first wavelength band filtering film on the array substrate does not overlap with an orthographic projection of the electroluminescent components on the array substrate.

3. The electroluminescent display panel according to claim 2, wherein the first wavelength band filtering firm comprises high-transmission color resistant which transmits near-infrared light and has a transmittance of near-infrared light of 90%.

4. The electroluminescent display panel according to claim 2, wherein the photosensitive device is in a same layer as the electroluminescence components.

5. The electroluminescent display panel according to claim 1, further comprising a light shielding structure around each of the photosensitive units to ensure each of the photosensitive units is only exposed to light on a side facing away from the array substrate.

6. The electroluminescent display panel according to claim 5, wherein the light shielding structure comprises a black matrix.

7. The electroluminescent display panel according to claim 1, wherein the non-visible light spectrum includes infrared light or ultraviolet light.

8. The electroluminescent display panel according to claim 1, wherein the mask layer comprises a second wavelength band filtering film in each of the second regions, and the second wavelength band filtering film is configured to transmit only the light in the visible light spectrum.

9. The electroluminescent display panel according to claim 8, wherein the second wavelength band filter film comprises glass materials or resin materials.

10. The electroluminescent display panel according to claim 1, wherein the array substrate further comprises first driving circuits for driving the electroluminescent components, and second driving circuits for driving the photosensitive units, wherein
the first driving circuits are disposed in the same layer as the second driving circuits;
the electroluminescent components are above the first driving circuits respectively; and
the photosensitive units are above the second driving circuits respectively.

11. The electroluminescent display panel according to claim 10, comprising a plurality of pixel units, each of the pixel units comprises more than one of the electroluminescent components, and each of the photosensitive units is between two adjacent pixel units.

12. The electroluminescent display panel according to claim 11, further comprising a polarizer and a ¼ wave plate between the electroluminescent components and the mask layer or between the mask layer and the package cover.

13. The electroluminescent display panel according to claim 1, wherein the electroluminescent components are configured to emit light of different primary colors respectively.

14. The electroluminescent display panel according to claim 1, wherein the electroluminescent components are configured to emit white light, and a color film layer is between each of the electroluminescent components and the package cover and configured to convert the white light into a light of a primary color.

15. The electroluminescent display panel according to claim 14, wherein an area of the mask layer corresponding to each of the electroluminescent components is multiplexed into the color film layer.

16. The electroluminescent display panel according to claim 1, wherein the electroluminescent components are configured to emit blue light, a color conversion layer is between each of the electroluminescent components and the package cover and configured to convert the blue light into a light of a primary color.

17. The electroluminescent display panel according to claim 16, wherein the mask layer is on a side of the color conversion layer facing the package cover.

18. The electroluminescent display panel according to claim 1, wherein the first regions and the second regions are alternately arranged, and a width or diameter of each of the first regions is in a range between about 10 μm and about 100 μm.

19. A display apparatus, comprising the electroluminescent display panel according to claim 1.

20. The display apparatus of claim 19, further comprising an image processing module, wherein the image processing module is configured to acquire signals provided by the photosensitive units and process the signals to form an image of a scene.
